(19) United States
(12) Patent Application Publication
(10) Pub. No.: US 2007/0210374 A1
(43) Pub. Date: Sep. 13, 2007

(54) VERTICAL-TYPE SURROUNDING GATE SEMICONDUCTOR DEVICE

(76) Inventor: Hsiao-Che Wu, Taoyuan Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,906

(22) Filed: May 25, 2006

(30) Foreign Application Priority Data
Mar. 10, 2006 (TW) 95108075

(51) Int. Cl. H01L 31/00

(52) U.S. Cl. 257/329

(57) ABSTRACT

A vertical-type surrounding gate semiconductor device is described. The semiconductor device comprises a pillar substrate, a collar oxide layer, a metal layer, a drain region, a ground line, a source region, a bit line, a word line, a gate and a gate dielectric layer. The ground line is formed in an opening of the pillar substrate and electrically connected to the pillar substrate, and covers the collar oxide layer and the metal layer. The drain region is formed on the top of the pillar substrate and in the upper portion of the opening. The gate is formed among the word line, the bit line and the pillar substrate. The gate dielectric layer is formed among the gate, the source region, the drain region, the bit line and the pillar substrate.

### CROSS-REFERENCE TO RELATED APPLICATION

This application claims the priority benefit of Taiwan application serial no. 95108075, filed on Mar. 10, 2006. All disclosure of the Taiwan application is incorporated herein by reference.

### BACKGROUND OF THE INVENTION

1. Field of Invention

The present invention relates to a semiconductor device. More particularly, the present invention relates to a semiconductor device with a vertical-type surrounding gate.

2. Description of Related Art

With the miniaturization of devices, in order to satisfy different applications of the integrated circuit industry in future, at present, the transistor configuration of semiconductor devices is progressing from a planar gate to a vertical gate.

FIG. 1A is a schematic stereogram of a transistor of a conventional vertical-type gate semiconductor device. FIG. 1B is a schematic sectional view of FIG. 1A along the section line I-I′.

Referring to FIGS. 1A and 1B, the vertical-type gate transistor comprises a pillar substrate 100, a gate oxide layer 102, a gate 104, a source region 106 and a drain region 108. The source region 106 and the drain region 108 are respectively disposed on two ends of the pillar substrate 100. The gate 104 surrounds the periphery of the pillar substrate 100. The gate oxide layer 102 is disposed between the pillar substrate 100 and the gate 104, and surrounds the sidewall of the pillar substrate 100. The aforementioned vertical-type gate transistor is also referred to as a vertical-type surrounding gate structure.

However, at present, the most serious problem existing in a common vertical-type surrounding gate semiconductor device is that a floating body effect is generated. The so-called floating body effect refers to that when a certain amount of charges accumulates in a channel in the semiconductor device, not only the threshold voltage of the device is affected, but also the current of the drain region may be suddenly increased. Furthermore, due to the floating body effect, the device may be automatically turned on even if a voltage is not applied yet, thus affecting the reliability and stability of the device and causing a leakage current.

Some patents/patent applications have disclosed the related technologies, such as U.S. Pat. No. 6,946,700, U.S. Pat. No. 6,806,140 and U.S. Patent Application No. 20050001257. The aforementioned documents are the references of the present invention.

### SUMMARY OF THE INVENTION

Accordingly, the object of the present invention is to provide a vertical-type surrounding gate semiconductor device capable of inhibiting the floating body effect, thereby avoiding various derived problems.

The vertical-type surrounding gate semiconductor device provided by the present invention comprises a pillar substrate, a collar oxide layer, a first metal layer, a drain region, a ground line, a source region, a bit line, a second metal layer, a word line, a gate and a gate dielectric layer. The pillar substrate has an opening. The collar oxide layer is disposed on the sidewall of the lower portion of the opening. The first metal layer is disposed on the bottom of the opening and on the surface of the collar oxide layer. The drain region is disposed in the top of the substrate and the upper portion of the opening. Additionally, the ground line is disposed in the opening under the drain region and electrically connected to the pillar substrate under the opening, and covers the collar oxide layer and the first metal layer. The source region is disposed in the pillar substrate and surrounds the pillar substrate in correspondence with the collar oxide layer. The bit line is disposed on the sidewall of the pillar substrate and surrounds a part of the surface of the source region. The second metal layer is disposed between the bit line and the source region. The word line is disposed above the bit line and surrounds the periphery of the pillar substrate. The gate is disposed among the word line, the bit line and the pillar substrate, and surrounds the sidewall of the pillar substrate. The gate dielectric layer is disposed among the gate, the source region, the drain region, the bit line and the pillar substrate.

Another vertical-type surrounding gate semiconductor device provided by the present invention comprises a pillar substrate, a collar oxide layer, a conductive layer, a drain region, a source region, a gate and a gate dielectric layer. The pillar substrate has an opening. The collar oxide layer is disposed on the sidewall of the opening. The conductive layer is disposed in the opening and electrically connected to the pillar substrate under the opening, and covers the collar oxide layer. The drain region is disposed on the top of the pillar substrate and electrically connected to the conductive layer. The source region is disposed in the pillar substrate in correspondence with the collar oxide layer. The gate surrounds the sidewall of the pillar substrate and disposed on a part of the drain region and a part of the source region. The gate dielectric layer is disposed between the gate and the pillar substrate.

The aforementioned semiconductor device employs the ground line formed in the pillar substrate for leading charges out, so as to avoid the problem of charge accumulation and inhibit the floating body effect. As such, the reliability of the device is improved and various derived problems caused by the floating body effect are avoided. On the other hand, the ground line is formed in the pillar substrate without occupying the usable area of the device, so the manufacturing cost is saved.

In order to make the aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic stereogram of a transistor of a conventional vertical-type gate semiconductor device.

FIG. 1B is a schematic sectional view of FIG. 1A along the section line I-I′.

FIG. 2 is a schematic sectional view of the vertical-type surrounding gate semiconductor device according to one embodiment of the present invention.

FIGS. 3-20 are schematic views of the work flow of manufacturing the vertical-type surrounding gate semiconductor device according to one embodiment of the present invention, wherein subgraph (a) is a schematic top view, subgraph (b) is a schematic sectional view along the section line A-A′, and subgraph (c) is a schematic sectional view along the section line B-B′.

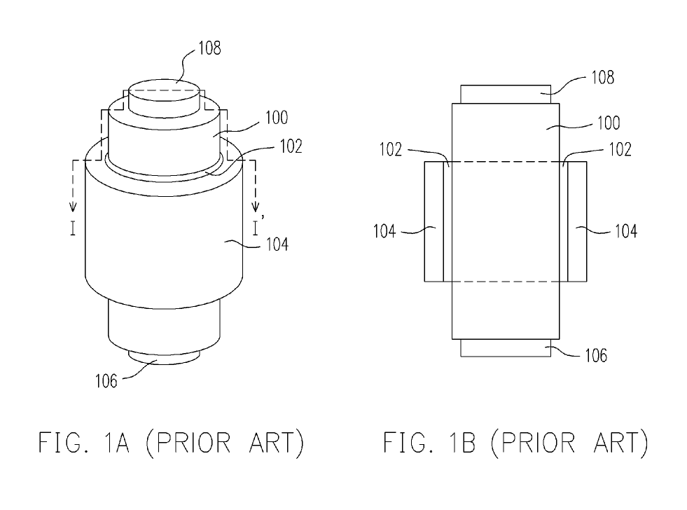

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

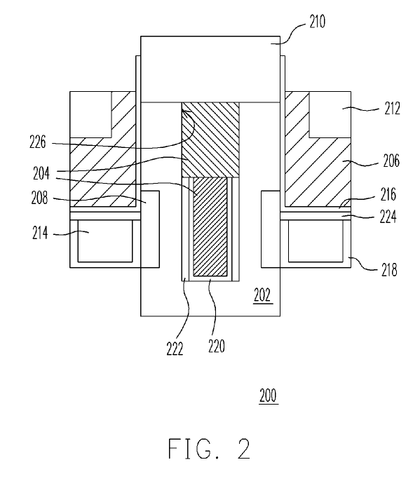

FIG. 2 is a schematic sectional view of the vertical-type surrounding gate semiconductor device according to one embodiment of the present invention.

Referring to FIG. 2, the vertical-type surrounding gate semiconductor device 200 comprises a pillar substrate 202, a ground line 204, a gate 206, a source region 208, a drain region 210, a word line 212, a bit line 214, a gate dielectric layer 216, metal layers 218 and 220, a collar oxide layer 222 and a dielectric layer 224.

The pillar substrate 202 has an opening 226. The collar oxide layer 222 is disposed on the sidewall of the lower portion of the opening 226. The metal layer 220 is disposed on the bottom of the opening 226 and the surface of the collar oxide layer 222. The collar oxide layer 222 is, for example, a silicon oxide layer, and is formed by, for example, a chemical vapor deposition (CVD) process with TEOS as a main reaction gas. The material of the metal layer 220 is, for example, titanium metal, titanium nitride, or an alloy thereof. Furthermore, a part of the metal layer 220 contacting the pillar substrate 202 on the bottom of the opening 226 is reacted to form a metal silicide layer, thereby reducing a contact resistance and improving the efficiency of the device. The source region 208 is disposed in the pillar substrate 202 and surrounds the pillar substrate 202 in correspondence with the collar oxide layer 222. The source region 208 is, for example, a doped region, and is formed by, for example, a plasma doping process. The drain region 210 is disposed in the top of the pillar substrate 202 and the upper portion of the opening 226, and is, for example, an ion implant region formed by, for example, an ion implant process.

Additionally, the bit line 214 is disposed on the sidewall of the pillar substrate 202 and surrounds a part of the surface of the source region 208. The material of the bit line 214 is, for example, tungsten metal, tungsten nitride, or an alloy thereof. The metal layer 218 is disposed between the bit line 214 and the source region 208 and the material thereof is, for example, titanium metal, titanium nitride, or an alloy thereof. Similarly, the part of the metal layer 218 contacting the source region 208 is reacted to form a metal silicide layer. The word line 212 is disposed above the bit line 214 and surrounds the periphery of the pillar substrate 202. The material of the word line 212 is, for example, tungsten metal, tungsten nitride, or an alloy thereof. The gate 206 is disposed among the word line 212, the bit line 214 and the pillar substrate 202 and surrounds the sidewall of the pillar substrate 202. The gate 206 is, for example, a conductive layer made of, for example, poly-silicon. The gate dielectric layer 216 is disposed among the gate 206, the source region 208, the drain region 210, the bit line 214 and the pillar substrate 202. The gate dielectric layer 216 is, for example, a high-K dielectric layer, and the material of the high-k dielectric layer is, for example, HfSiO, HfSiN, HfSiON, or HfAlO. The dielectric layer 224 is disposed between the gate dielectric layer 216 and the bit line 214 and the material thereof is, for example, silicon oxide, silicon nitride, or another suitable dielectric material. In this embodiment, the dielectric layer 224 is illustrated by only one layer, but the dielectric layer 224 can be of a different structure according to different processes.

Furthermore, the vertical-type surrounding gate semiconductor device 200 further comprises a ground line 204. The ground line 204 is disposed in the opening 226 under the drain region 210 and covering the collar oxide layer 222 and the metal layer 220. Further, the ground line 204 is electrically connected to the pillar substrate 202. The aforementioned ground line 204 is, for example, a conductive layer made of, for example, poly-silicon.

It should be noted that since the ground line 204 is electrically connected to the pillar substrate 202 under the opening 226, charges can be drawn out through the ground line 204, so as to avoid the problem of charge accumulation. As such, the floating body effect is inhibited and various derived problems can be avoided. Furthermore, the semiconductor device of the present invention employs the ground line 204 formed in the pillar substrate 202, so that the usable area of the device is not occupied.

Next, the method of manufacturing the vertical-type surrounding gate semiconductor device is illustrated in an embodiment below.

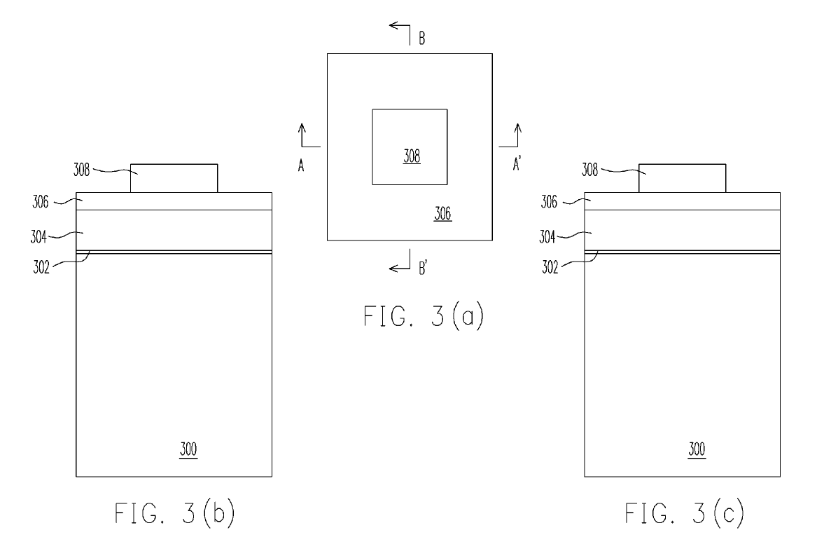

FIGS. 3-20 are schematic views of the work flow of manufacturing the vertical-type surrounding gate semiconductor device according to one embodiment of the present invention, wherein subgraph (a) is a schematic top view, subgraph (b) is a schematic sectional view along the section line A-A′, and subgraph (c) is a schematic sectional view along the section line B-B′.

First, referring to FIGS. 3(a), 3(b) and 3(c) together, a substrate 300 such as a silicon substrate is provided. Then, a pad oxide layer 302, a pad nitride layer 304, and a borosilicate glass (BSG) layer 306 are sequentially formed on the substrate 300. The pad oxide layer 302 is, for example, a silicon oxide layer or another suitable oxide layer. The pad nitride layer 304 is, for example, a silicon nitride layer or another suitable nitride layer. The pad oxide layer 302, the pad nitride layer 304 and the BSG layer 306 are formed, for example, by CVD. Subsequently, a patterned photoresist layer 308 is formed on the dielectric layer 306, and covers an active area (AA) and serves as a mask layer for forming a shallow trench isolation (STI) in subsequent processes.

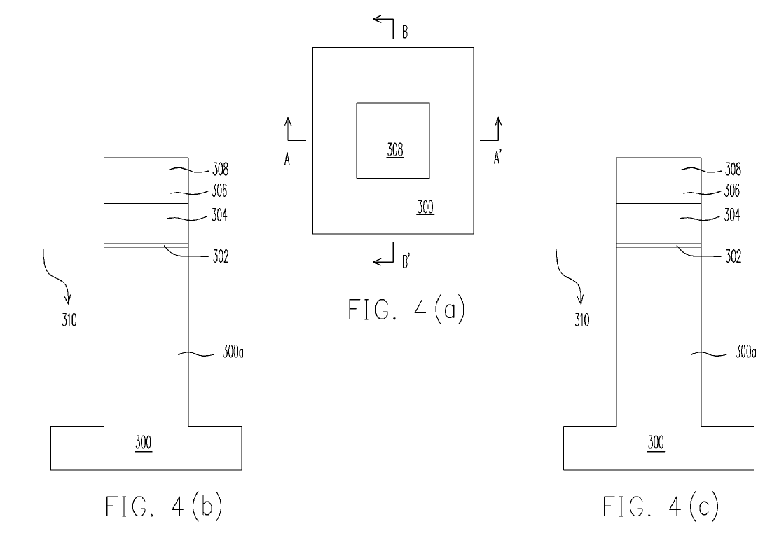

Then, referring to FIGS. 4(a), 4(b) and 4(c) together, an etching process is performed to remove the BSG layer 306, the pad nitride layer 304, the pad oxide layer 302 and a part of the substrate 300 not covered by the patterned photoresist layer 308. As such, a pillar substrate 300a is formed in the active area and a trench 310 of the shallow trench isolation is formed around the periphery of the active area. After the BSG layer 306 undergoes an etching process, the problem of the rounding edges and corners of the pad nitride layer 304 is avoided.

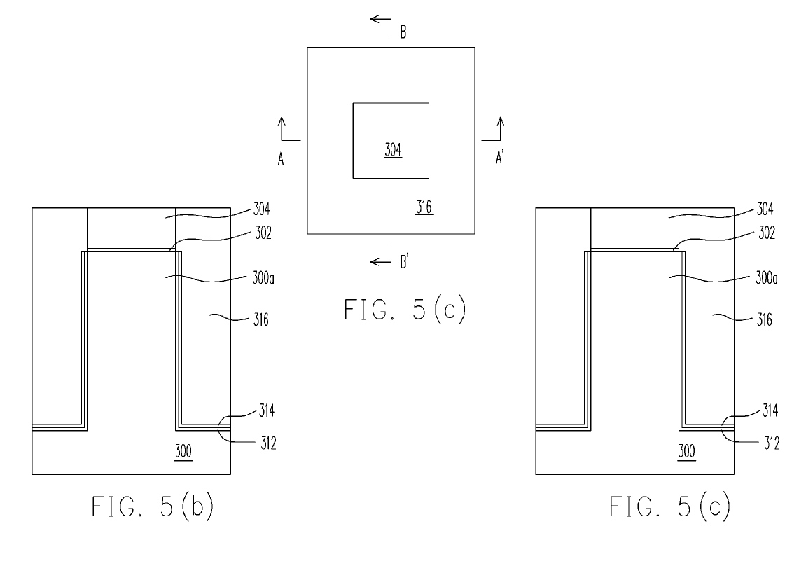

Next, referring to FIGS. 5(a), 5(b) and 5(c) together, first the patterned photoresist layer 308 is removed. Then, the BSG layer 306 is further removed, for example, by a wet etching process. After that, a liner oxide layer 312 and a liner nitride layer 314 are sequentially formed on the sidewall of the substrate 300a and the surface of the substrate 300. The liner oxide layer 312 is, for example, a silicon oxide layer or another suitable oxide layer, and the liner nitride layer 314 is, for example, a silicon nitride layer or another suitable nitride layer. The liner oxide layer 312 and the liner nitride layer 314 are both formed, for example, by CVD. Subsequently, an oxide layer 316, deposited using TEOS as a main reaction gas, is filled into the trench 310. After the oxide layer 316 is formed, the chemical mechanical polishing (CMP) process is further performed to planarize the surface of the oxide layer 316.

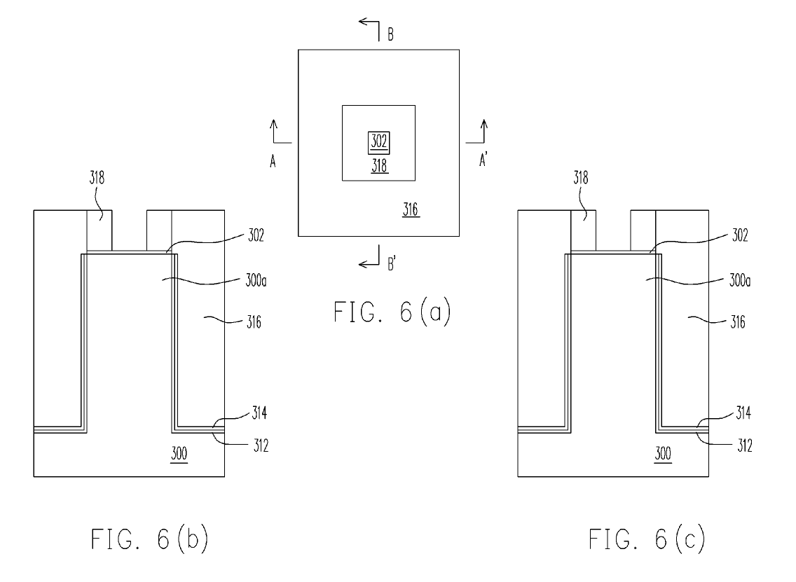

Then, referring to FIGS. 6(a), 6(b) and 6(c) together, the pad nitride layer 304 is removed, for example, by a wet etching process. Then, a nitride material layer (not shown) is conformably formed above the substrate 300 to cover the pad oxide layer 302 and the oxide layer 316. Subsequently, an etching process is performed to remove a portion of the nitride material layer until exposing the surface of the pad oxide layer 302, so as to form a ring nitride layer 318 above the pillar substrate 300a.

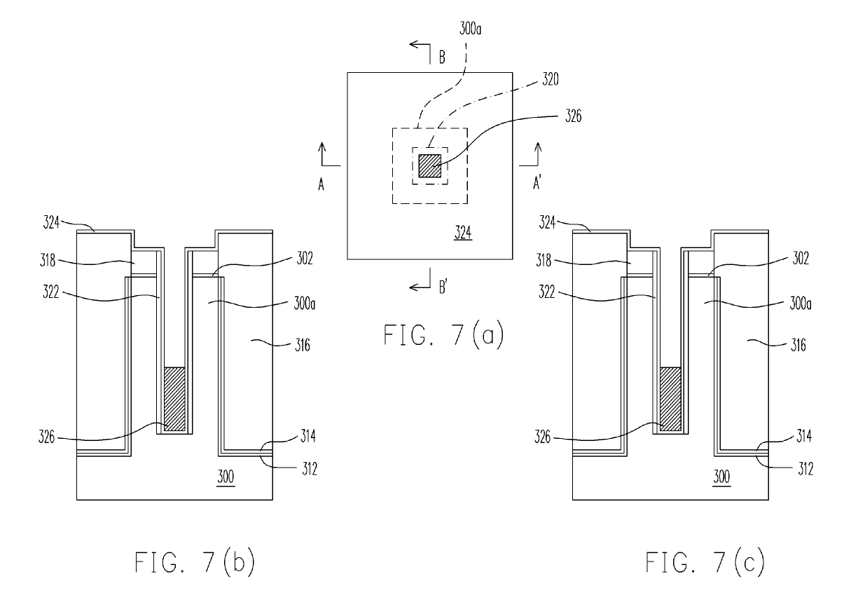

Subsequently, referring to FIGS. 7(a), 7(b) and 7(c) together, the exposed pad oxide layer 302 is removed until exposing the surface of the pillar substrate 300a. In this step, a portion of the nitride layer 31 8 is removed, such that the upper surface of the nitride layer 318 is lower than that of the oxide layer 316. Then, an etching process with the nitride layer 318 as a mask is performed to remove a portion of the pillar substrate 300a to form an opening 320. Then, a ring collar oxide layer 322 is formed on the sidewall of the opening 320. The collar oxide layer 322 is, for example, a silicon oxide layer formed by using TEOS as a main reaction gas and the forming method thereof involves, for example, conformably depositing an oxide material layer (not shown) above the substrate 300 and then removing a portion of the oxide material layer until exposing the surface of the pillar substrate 300a. Then, a metal layer 324 is conformably formed above the substrate 300 and the material thereof is, for example, titanium metal. It is noted that a part of the metal layer 324 may contact and react with the pillar substrate 300a on the bottom of the opening 320 to form a metal silicide layer wherein, so as to reduce the contact resistance and improve the efficiency of the device. Next, a conductive layer 326 is filled into the opening 320. The material of the conductive layer 326 is, for example, poly-silicon, or another suitable conductive material. The conductive layer 326 is formed, for example, by depositing a conductive material layer (not shown) to fill up the opening 320 and then performing an etching process to remove a part of the conductive material layer.

In one embodiment, after the conductive layer 326 is formed, for example, a wet removing process is performed to remove the residual conductive material layer on the metal layer 324 on the sidewall of the opening 320, so as to facilitate removing the metal layer 324 in the subsequent processes. The wet removing process involves, for example, performing an isotropic etching process by using, for example, KOH solution as the etching solution.

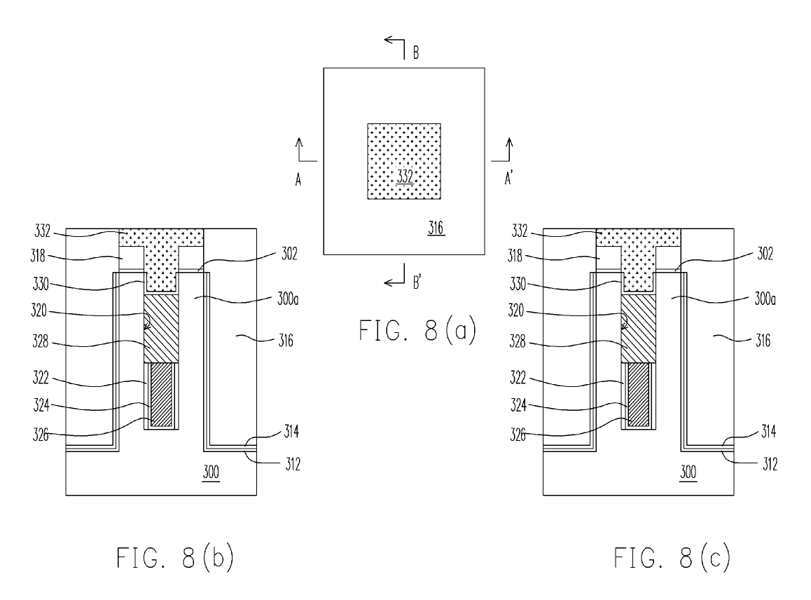

Then, referring to FIGS. 8(a), 8(b) and 8(c) together, the metal layer 324 not covered by the conductive layer 326 is removed by, for example, an isotropic etching process by using, for example, hydrofluoric acid solution (H₂O:HF=10:1) as the etching solution under a temperature of, for example, 20° C. Then, the collar oxide layer 322 exposed by the conductive layer 326 and the metal layer 324 is removed. After that, a conductive layer 328 is formed in the opening 320 to cover the conductive layer 326, the metal layer 324 and the collar oxide layer 322. The material of the conductive layer 328 is, for example, poly-silicon or another suitable conductive material and the forming method thereof involves, for example, depositing a conductive material layer (not shown) to fill up the opening 320 and performing an etching process to remove a part of the conductive material layer.

Afterwards, a liner nitride layer 330, such as a silicon nitride layer or another suitable nitride layer, is formed on the sidewall of the opening 320 and the surface of the conductive layer 328 through a process of, for example, CVD. Then, a conductive layer 332 is formed to cover the liner nitride layer 330 and the nitride layer 318. The method of forming the conductive layer 332 involves, for example, forming a conductive material layer (not shown) by CVD to fill up the opening 320 and removing the residual conductive material layer by CMP, so as to planarize the surface of the conductive layer 332.

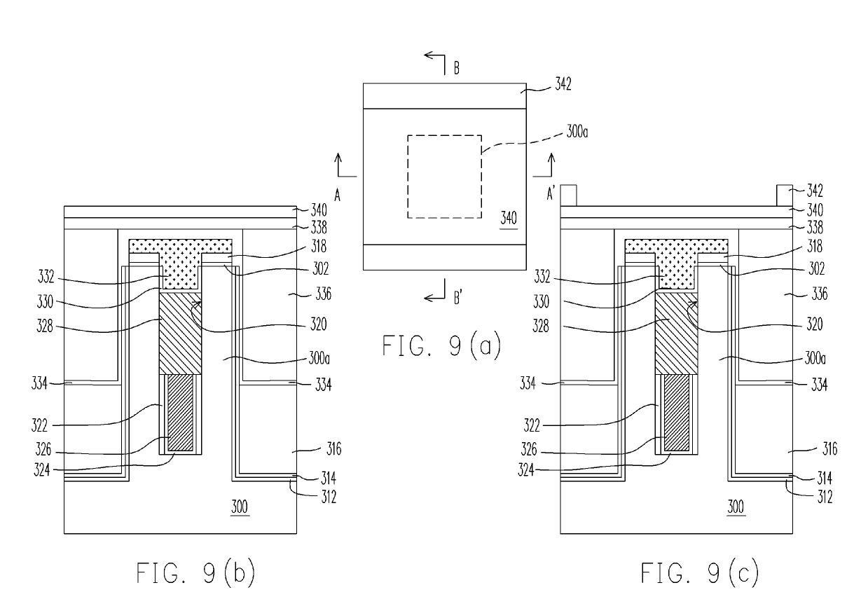

Then, referring to FIGS. 9(a), 9(b) and 9(c) together, a portion of the oxide layer 316 is etched with a conductive layer 332 as a hard mask. After that, a liner nitride layer 334, such as a silicon nitride layer or another suitable nitride layer, is conformably formed above the substrate 300 through a process of, for example, CVD. Subsequently, an oxide layer 336 is formed on the liner nitride layer 334. The oxide layer 336 is formed by, for example, using TEOS as a main reaction gas. Then, a CMP process is performed to remove the residual oxide layer, thereby planarizing the surface of the oxide layer 336. Next, a conductive layer 338, a nitride layer 340 and a patterned photoresist layer 342 are sequentially formed over the oxide layer 336 and the liner nitride layer 334. The patterned photoresist layer 342 exposes the active area and a portion of the shallow trench isolation area. The material of the conductive layer 338 is, for example, poly-silicon or another suitable conductive material, and the method of forming the conductive layer is, for example, CVD. The nitride layer 340 is, for example, a silicon nitride layer or another suitable nitride layer, and the forming method thereof is, for example, CVD.

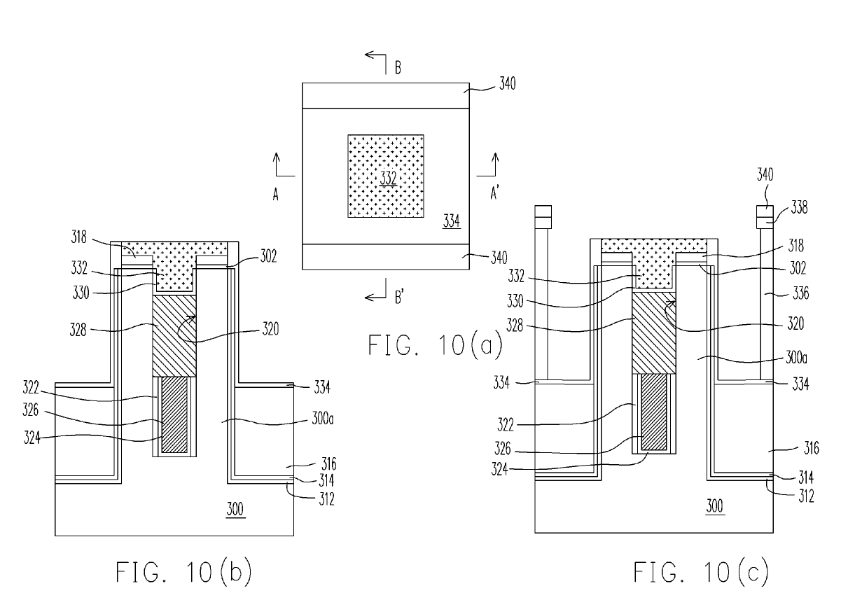

Subsequently, referring to FIGS. 10(a), 10(b) and 10(c) together, the exposed nitride layer 340 is removed with the patterned photoresist layer 342 as a mask. Then, the patterned photoresist layer 342 is removed. After that, by using the nitride layer 340 as a mask and the liner nitride layer 334 as an etching stop layer, a part of the conductive layer 338 and a portion of the oxide layer 336 are removed to expose the surface of the liner nitride layer 334. In the step, a portion of the liner nitride layer 334 above the conductive layer 332 may be removed, and even the liner nitride layer 334 above the conductive layer 332 may be removed to expose the surface of the conductive layer 332.

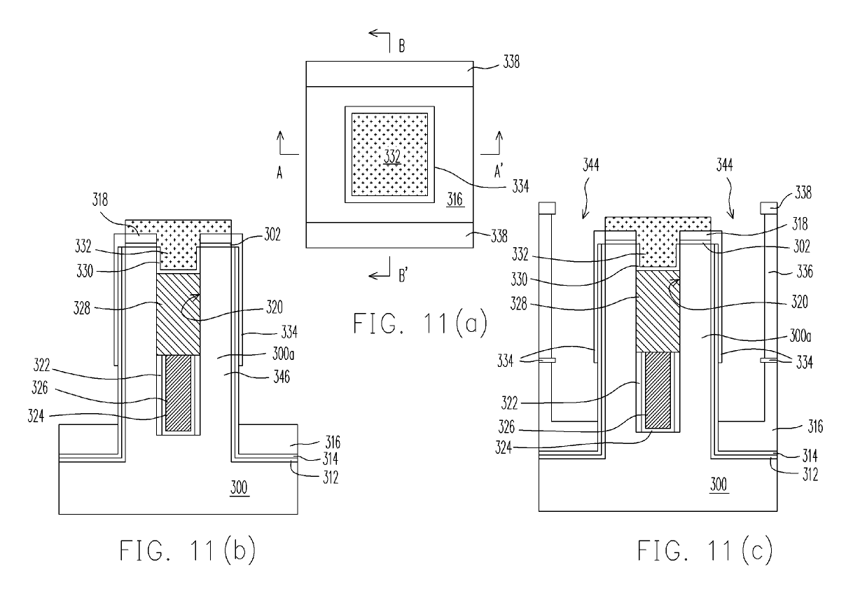

Next, referring to FIGS. 11(a), 11(b) and 11(c) together, the exposed nitride layer 340 and liner nitride layer 334 are removed to expose the surface of the oxide layer 316. After that, by using the conductive layer 332 and 338 as a hard mask, a part of the oxide layer 316 is removed to form a trench 344. Then, an isotropic etching process is performed to remove a portion of the oxide layer 336 and a portion of the oxide layer 316 on the sidewall of the trench 344.

In one embodiment, after a portion of the oxide layer 336 and a portion of the oxide layer 316 on the sidewall of the trench 344 are removed, for example, a wet removing process is further performed to remove the residual oxide material layer on the sidewall of the active area. The wet removing process involves, for example, performing an isotropic etching process by using, for example, a diluted hydrofluoric acid solution (H2O:HF=200:1) as the etching solution, under a temperature of, for example, 30° C.

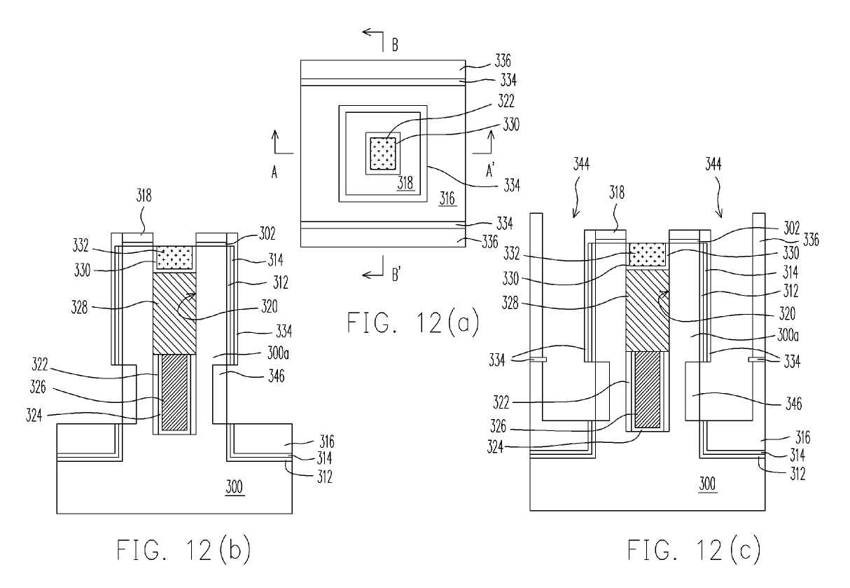

Subsequently, referring to FIGS. 12(a), 12(b) and 12(c) together, the conductive layer 338 and a portion of the conductive layer 332 are removed by, for example, using a potassium hydroxide solution under a temperature of 80° C. Then, the liner nitride layer 314 and the liner oxide layer 312 on the sidewall of the trench 344 are removed to expose the surface of the sidewall of the pillar substrate 300a. After that, a plasma doping process is performed on the surface of the exposed sidewall of the pillar substrate 300a to form a ring doped region 346 in the pillar substrate 300a, in which the ring doped region 346 is used as the source region of a memory device.

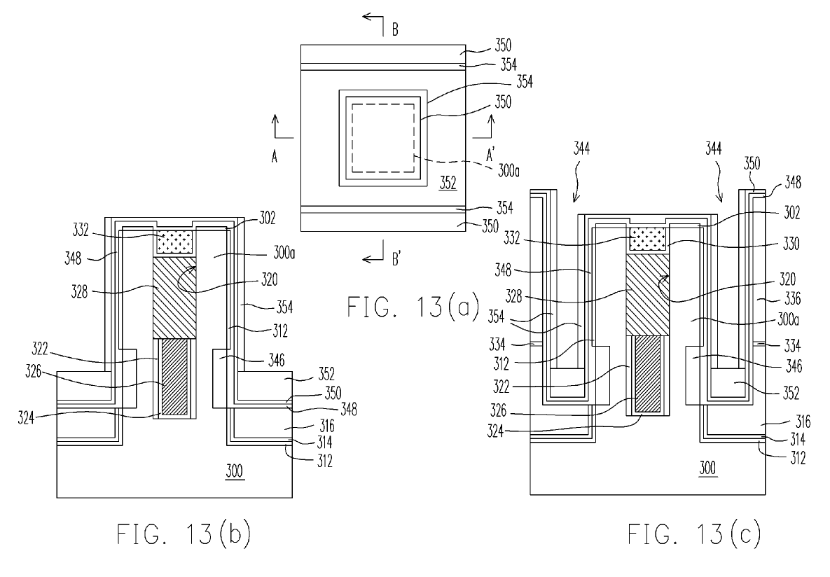

After that, referring to FIGS. 13(a), 13(b) and 13(c) together, an etching process is performed to remove the nitride layer 318, a portion of the liner nitride layer 334 and a portion of the liner nitride layer 314. Then, a liner oxide layer 348 and a liner nitride layer 350 are conformably sequentially formed above the substrate 300. Next, an oxide layer 352 is filled into the trench 344 to cover the liner nitride layer 350. Then, an etching process is performed to remove a part of the oxide layer 352, such that the upper surface of the oxide layer 352 is lowered to expose a part of the doped region 346. Subsequently, a conductive layer 354 is formed on the surface of the liner nitride layer 350 on the sidewall of the trench 344. The material of the conductive layer 354 is, for example, poly-silicon or another suitable conductive material, and the forming method thereof is, for example, CVD. Then, an etching process is performed to remove a part of the conductive layer 354 and expose the oxide layer 352.

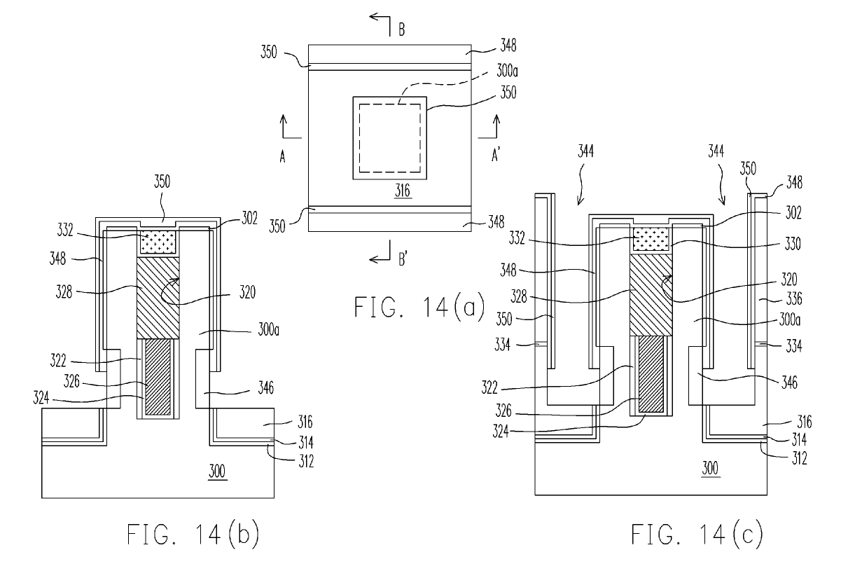

Subsequently, referring to FIGS. 14(a), 14(b) and 14(c) together, the oxide layer 352 is removed by an isotropic etching process by using, for example, BHF as the etching solution under a temperature of, for example, 20° C. Then, a portion of the exposed liner nitride layer 350 is removed by, for example, an isotropic etching process by using, for example, phosphoric acid as the etching solution under a temperature of, for example, 160° C. Subsequently, the conductive layer 354 is removed by, for example, an isotropic etching process by using, for example, potassium hydroxide as the etching solution under a temperature of, for example, 80° C. Next, the liner oxide layer 348 on the sidewall of the trench 344 is removed by, for example, an isotropic etching process by using, for example, BHF solution as the etching solution under a temperature of, for example, 20° C.

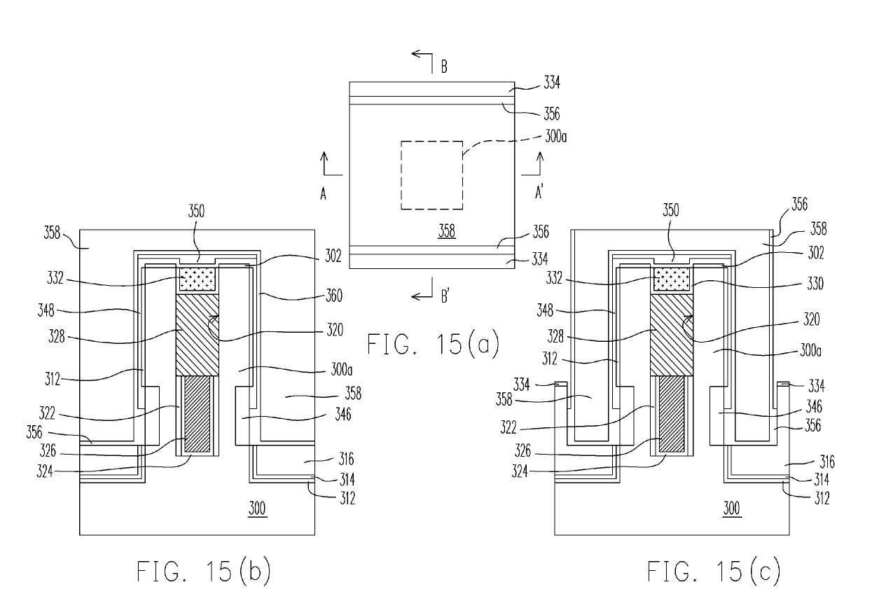

Then, referring to FIGS. 15(a), 15(b) and 15(c) together, the liner nitride layer 350 on the sidewall of the trench 344 is removed by, for example, an isotropic etching process by using, for example, a phosphoric acid solution as the etching solution. Subsequently, a metal layer 356 is conformably formed above the substrate 300. The part of the metal layer 356 contacting the doped region 346 forms a metal silicide layer. The material of the metal layer 356 is, for example, titanium metal, titanium nitride, or an alloy thereof. Then, a metal layer 358 is formed on the metal layer 356 and filled up the trench 344 and the material thereof is, for example, tungsten metal. Afterwards, the oxide layer 336 and a portion of liner oxide layer 348 are removed to expose the surface of the liner nitride layer 334. The method of removing the oxide layer 336 and a portion of liner oxide layer 348 is an isotropic etching process by using, for example, potassium hydroxide as the etching solution under a temperature of, for example, 80° C.

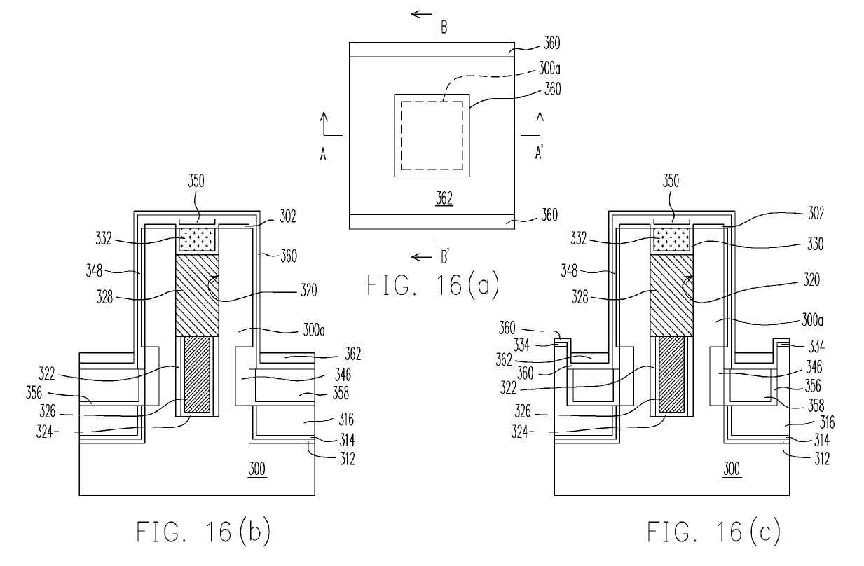

Afterwards, referring to FIGS. 16(a), 16(b) and 16(c) together, an etching back process is performed to remove a portion of the metal layer 356 and a portion of the metal layer 358 to expose a portion of the surface of the doped region 346, wherein the exposed portion of the doped region 346 is, for example, the metal silicide formed of the portion of the metal layer 356 contacting the doped region 346. The metal layer 358 serves as the bit line of the memory device. Next, a nitride layer 360 is conformably formed above the substrate 300 and then an oxide layer 362 is formed above the nitride layer 360, wherein the oxide layer 362 is formed by, for example, depositing an oxide material layer by using TEOS as a main reaction gas and then removing a portion of the oxide material layer through an etching process.

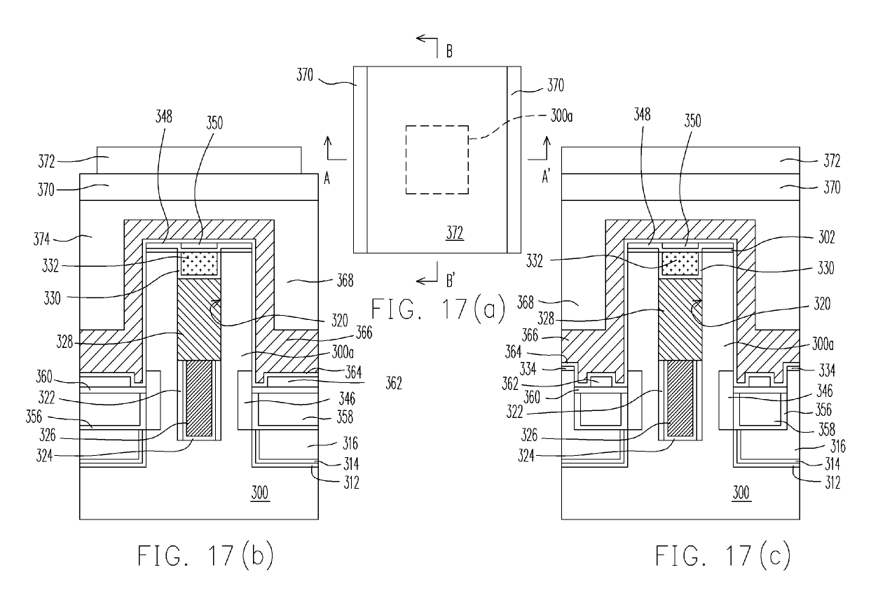

Subsequently, referring to FIGS. 17(a), 17(b) and 17(c) together, an etching process is performed to remove a portion of the nitride layer 360. Then, the liner oxide layer 348 is removed to expose the sidewall of the pillar substrate 300a, and the removing method is, for example, an isotropic etching process by using, for example, diluted hydrofluoric acid (H₂O:HF=200:1) as the etching solution under a temperature of, for example, 30° C. Then, a dielectric layer 364 is conformably formed above the substrate 300 and serves as the gate dielectric layer of the memory device. The dielectric layer 364 is, for example, a high-K dielectric layer and the material thereof is, for example, HfSiO, HfSiN, HfSiON, HfAlO, and so on. Next, a conductive layer 366 is formed on the dielectric layer 364 and the material thereof is, for example, poly-silicon. After that, a metal layer 368 is formed on the conductive layer 366 and the material thereof is, for example, tungsten metal, tungsten nitride, or an alloy thereof. Then, a nitride layer 370 and a patterned photoresist layer 372 are sequentially formed over the metal layer 368.

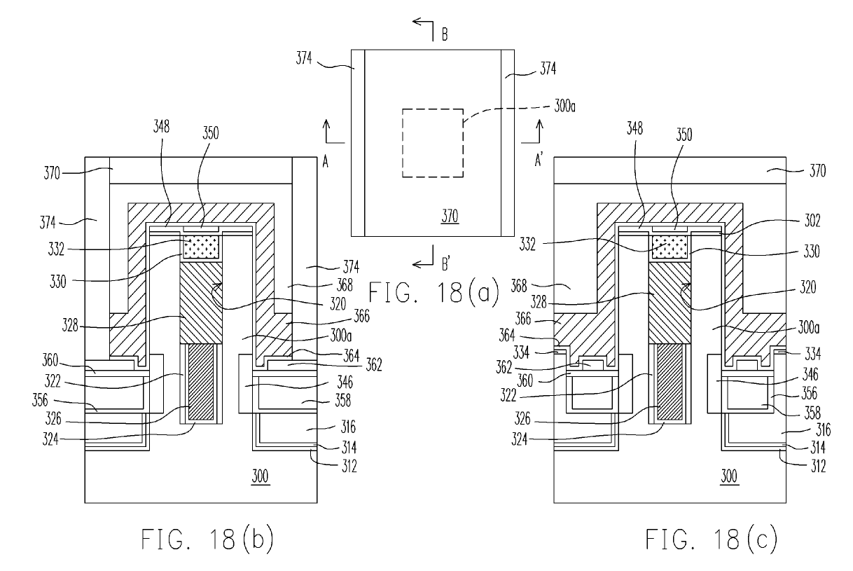

Next, referring to FIGS. 18(a), 18(b) and 18(c) together, by using the patterned photoresist layer 372 as a mask, a portion of the nitride layer 370 is removed to expose the surface of the metal layer 368. Then, the patterned photoresist layer 372 is removed. Subsequently, an etching process is performed to remove the metal layer 368, the conductive layer 366, and the dielectric layer 364 not covered by the nitride layer 370 until exposing the surface of the oxide layer 362. Then, an oxide layer 374 is formed on the oxide layer 362 and then a CMP is performed to planarize the surface of the oxide layer 374 and expose the nitride layer 370.

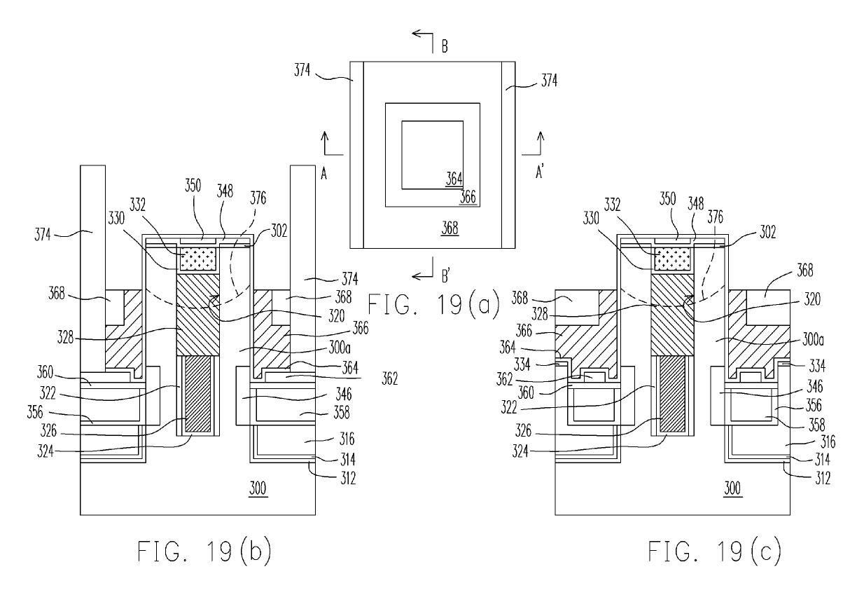

Then, referring to FIGS. 19(a), 19(b) and 19(c) together, the nitride layer 370 is removed. Subsequently, an etch-back process is performed to remove a portion of the metal layer 368. Next, a portion of the conductive layer 366 is removed to expose the dielectric layer 364. Subsequently, an ion implant process is performed to form an ion implant region 376 on the top of the substrate 300a as the drain region of the memory device. Particularly, the conductive layers 326 and 328 under the ion implant region 376 serve as the ground line of the semiconductor device and are used to inhibit the floating body effect, thereby improving the reliability of the device.

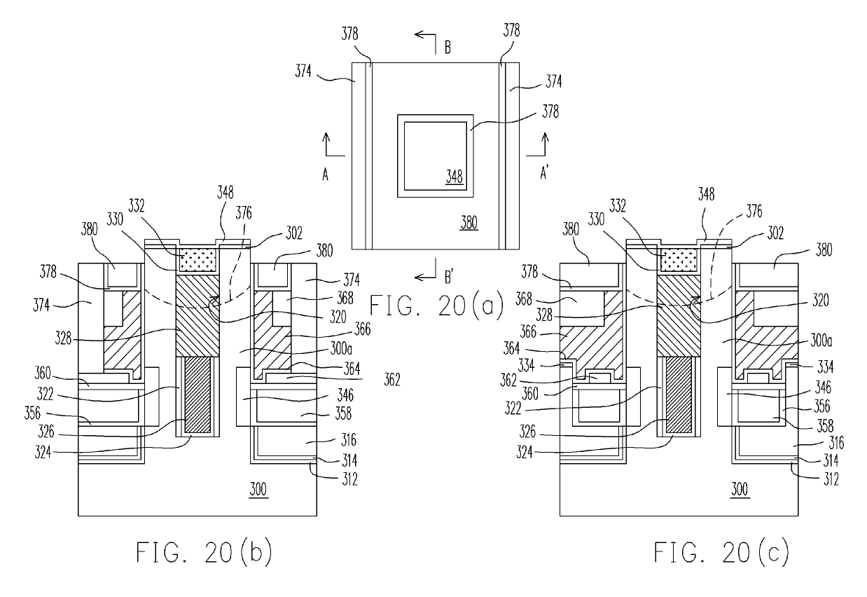

Finally, referring to FIGS. 20(a), 20(b) and 20(c) together, a liner nitride layer 378 is formed to conformably cover the oxide layer 374, the metal layer 368, the conductive layer 366 and the dielectric layer 364. Next, an oxide layer 380 is formed on the liner nitride layer 378. Subsequently, an etching process is performed to remove a portion of the oxide layer 374 and a portion of the oxide layer 380. Then, a portion of the liner nitride layer 378 is removed. Next, the dielectric layer 364 not covered by the liner nitride layer 378 is removed. In this step, a portion of the liner nitride layer 350 is also removed. As such, the vertical-type surrounding gate semiconductor device with the ground line is finished.

Of course, the aforementioned embodiment is not intended to limit the present invention and is one of various methods of manufacturing the vertical-type surrounding gate semiconductor device of the present invention.

In view of the above, as for the semiconductor device of the present invention, the ground line is formed in the pillar substrate and used to lead charges out, so as to avoid the problem of charge accumulation and inhibit the floating body effect. As such, the reliability of the device is improved and various derived problems due to the floating body effect are avoided. On the other hand, since the ground line is formed within the pillar substrate, the usable area of the device is not occupied, thereby saving manufacturing costs.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A vertical-type surrounding gate semiconductor device, comprising:
a pillar substrate, the pillar substrate having an opening;
a collar oxide layer disposed on a sidewall of a lower portion of the opening;
a first metal layer disposed on a bottom of the opening and on a surface of the collar oxide layer;
a drain region disposed in a top of the pillar substrate and in an upper portion of the opening;
a ground line disposed in the opening under the drain region, being electrically connected to the pillar substrate under the opening, and covering the collar oxide layer and the first metal layer;
a source region disposed in the pillar substrate and surrounding the pillar substrate in correspondence with the collar oxide layer;
a bit line disposed over a sidewall of the pillar substrate and surrounding a part of a surface of the source region;
a second metal layer disposed between the bit line and the source region;
a word line disposed above the bit line and surrounding a periphery of the pillar substrate;
a gate disposed among the word line, the bit line and the pillar substrate, and surrounding the sidewall of the pillar substrate; and
a gate dielectric layer disposed among the gate, the source region, the drain region, the bit line, and the pillar substrate.

2. The vertical-type surrounding gate semiconductor device as claimed in claim 1, wherein the ground line comprises a conductive layer.

3. The vertical-type surrounding gate semiconductor device as claimed in claim 2, wherein the conductive layer comprises poly-silicon.

4. The vertical-type surrounding gate semiconductor device as claimed in claim 1, wherein the source region comprises a doped region.

5. The vertical-type surrounding gate semiconductor device as claimed in claim 1, wherein the drain region comprises an ion implant region.

6. The vertical-type surrounding gate semiconductor device as claimed in claim 1, wherein the gate dielectric layer comprises a high-K dielectric layer.

7. The vertical-type surrounding gate semiconductor device as claimed in claim 6, wherein the high-K dielectric layer comprises HfSiO, HfSiN, HfSiON, or HfAlO.

8. The vertical-type surrounding gate semiconductor device as claimed in claim 1, wherein the word line comprises tungsten metal, tungsten nitride, or an alloy thereof.

9. The vertical-type surrounding gate semiconductor device as claimed in claim 1, wherein the bit line comprises tungsten metal, tungsten nitride, or an alloy thereof.

10. The vertical-type surrounding gate semiconductor device as claimed in claim 1, wherein the gate comprises a conductive layer.

11. The vertical-type surrounding gate semiconductor device as claimed in claim 10, wherein the conductive layer comprises poly-silicon.

12. The vertical-type surrounding gate semiconductor device as claimed in claim 1, wherein the first metal layer and the second metal layer comprise titanium metal, titanium nitride, or an alloy thereof.

13. The vertical-type surrounding gate semiconductor device as claimed in claim 1, wherein the collar oxide layer comprises a silicon oxide layer.

14. A vertical-type surrounding gate semiconductor device, comprising:
a pillar substrate, the pillar substrate having an opening;
a collar oxide layer disposed on a sidewall of the opening;
a conductive layer disposed in the opening and being electrically connected to the pillar substrate under the opening, and covering the collar oxide layer;
a drain region disposed on a top of the pillar substrate and being electrically connected to the conductive layer;
a source region disposed in the pillar substrate in correspondence with the collar oxide layer;
a gate surrounding a sidewall of the pillar substrate and being located over a part of the drain region and a part of the source region; and
a gate dielectric layer disposed between the gate and the pillar substrate.

15. The vertical-type surrounding gate semiconductor device as claimed in claim 14, wherein a material of the conductive layer comprises poly-silicon.

16. The vertical-type surrounding gate semiconductor device as claimed in claim 14, further comprising a metal layer disposed on a bottom of the opening and between the collar oxide layer and the conductive layer.

17. The vertical-type surrounding gate semiconductor device as claimed in claim 16, wherein a material of the metal layer comprises titanium metal, titanium nitride, or an alloy thereof.

18. The vertical-type surrounding gate semiconductor device as claimed in claim 14, further comprising a bit line under the gate and a word line above the gate.

19. The vertical-type surrounding gate semiconductor device as claimed in claim 14, wherein the gate dielectric layer comprises a high-K dielectric layer.

20. The vertical-type surrounding gate semiconductor device as claimed in claim 19, wherein a material of the high-K dielectric layer comprises HfSiO, HfSiN, HfSiON, or HfAlO.
